(19) United States
(12) Patent Application Publication
(10) Pub. No.: US 2011/0059246 A1
(43) Pub. Date: Mar. 10, 2011

(54) COATING APPARATUS AND COATING METHOD

(75) Inventors: Hidenori MIYAMOTO, Kawasaki-shi (JP); Kenji MARUYAMA, Kawasaki-shi (JP); Tadahiko HIRAKAWA, Kawasaki-shi (JP); Koichi MISUMI, Kawasaki-shi (JP)

(73) Assignee: TOKYO OHKA KOGYO CO., LTD., Kawasaki-shi (JP)

(21) Appl. No.: 12/875,613

(22) Filed: Sep. 3, 2010

(30) Foreign Application Priority Data
Sep. 8, 2009 (JP) 2009-207138
Aug. 17, 2010 (JP) 2010-182317

(51) Int. Cl. B05D 3/04; B05C 11/00; B05D 3/02

(52) U.S. Cl. 427/345; 118/64; 118/708; 427/383.1

(57) ABSTRACT

A coating apparatus including a coating part which applies a liquid material including an oxidizable metal on a substrate; a chamber having a coating space in which the coating part applies the liquid material on the substrate and a transport space into which the liquid material is transported; and an adjusting part which adjusts at least one of oxygen concentration and humidity inside the chamber.

### BACKGROUND OF THE INVENTION

1. Field of the Invention

The present invention relates to a coating apparatus and a coating method.

2. Description of the Related Art

A CIGS solar cell or a CZTS solar cell formed by semiconductor materials including a metal such as Cu, Ge, Sn, Pb, Sb, Bi, Ga, In, Ti, Zn, and a combination thereof, and a chalcogen element such as S, Se, Te, and a combination thereof has been attracting attention as a solar cell having high conversion efficiency (for example, see Patent Documents 1 to 3). For example, a CIGS solar cell has a structure in which a film including four types of semiconductor materials, namely, Cu, In, Ga, and Se is used as a light absorbing layer (photoelectric conversion layer).

In a CIGS solar cell or a CZTS solar cell, since it is possible to reduce the thickness of the light absorbing layer compared to a conventional solar cell, it is easy to install the CIGS solar cell on a curved surface and to transport the CIGS solar cell. For this reason, it is expected that CIGS solar cells can be used in various application fields as a high-performance, flexible solar cell. As a method of forming the light absorbing layer, a method of forming the light absorbing layer through depositing or sputtering is conventionally known (for example, see Patent Documents 2 to 5).

[Documents of Related Art]

[Patent Documents]

[Patent Document 1] Japanese Unexamined Patent Application, First Publication No. Hei 11-340482

[Patent Document 2] Japanese Unexamined Patent Application, First Publication No. 2005-51224

[Patent Document 3] Published Japanese Translation No. 2009-537997 of the PCT International Publication

[Patent Document 4] Japanese Unexamined Patent Application, First Publication No. Hei 1-231313

[Patent Document 5] Japanese Unexamined Patent Application, First Publication No. Hei 11-273783

[Patent Document 6] Japanese Unexamined Patent Application, First Publication No. 2005-175344

By contrast, as the method of forming the light absorbing layer, the present inventor propose a method of coating the semiconductor materials in the form of a liquid material on a substrate. In such a method of forming the light absorbing layer by coating the semiconductor materials in the form of a liquid material, the following problems arise.

Among the semiconductor materials, Cu, In, and the like are metals susceptible to oxidation (i.e., oxidizable metals). When a liquid material including such oxidized metals is coated on the substrate under the conditions in which the oxygen concentration or humidity is high, the oxidizable metal is likely to be oxidized, which may cause deterioration in the film quality of the coating film. This problem is not limited to the case of forming a semiconductor film of a CIGS solar cell, but may generally arise in a coating operation using a liquid material including the oxidizable metals.

In order to solve the above-described problem, for example, as described in Patent Document 6, a technology has been proposed in which a main chamber is maintained in a hermetic state by a nitrogen-circulation cleaning unit and nitrogen is circulated via a high-performance filter so as to maintain a clean state. However, since a coating operation is performed using an organic material such as a photoresist as a target solution and metal is not a main component thereof, it is difficult to solve the above-described problem.

### SUMMARY OF THE INVENTION

The present invention takes the above circumstances into consideration, with an object of providing a coating apparatus and a coating method capable of suppressing the deterioration in film quality of a coating film including oxidizable metal.

According to one aspect of the present invention, there is provided a coating apparatus including a coating part which applies a liquid material including an oxidizable metal on a substrate; a chamber having a coating space in which the coating part applies the liquid material on the substrate and a transport space into which the liquid material is transported; and an adjusting part which adjusts at least one of oxygen concentration and humidity inside the chamber.

According to the present invention, since it is possible to adjust at least one of the oxygen concentration and the humidity inside the chamber by the adjusting part, it is possible to prevent the oxidization of the liquid material or the oxidizable metal included in the liquid material. As a result, it is possible to prevent the deterioration in film quality of the coating film.

In the coating apparatus, the liquid material may include hydrazine.

In this embodiment, when the liquid material including hydrazine is coated on the substrate, since it is possible to suppress at least one of the oxygen concentration and the humidity inside the chamber, oxidization of hydrazine can be prevented.

In the coating apparatus, the adjusting part may include an inert gas supplying mechanism which supplies an inert gas to the inside of the chamber.

In this embodiment, by virtue of the adjusting part including an inert gas supplying mechanism which supplies the inert gas to the inside of the chamber, the inside of the chamber can be changed to an inert gas atmosphere, thereby enabling to reduce the oxygen concentration and the humidity inside the chamber.

In the coating apparatus, the adjusting part may include a detection part which detects the at least one of oxygen concentration and humidity, and the inert gas supplying mechanism may include a supply amount adjusting part which adjusts a supply amount of the inert gas on the basis of the detection result of the detection part.

In this embodiment, by virtue of adjusting the supply amount of the inert gas on the basis of the detection result of the detection part, it is possible to stably maintain the oxygen concentration and the humidity inside the chamber to be not more than a predetermined value.

In the coating apparatus, the adjusting part may include a second detection part which detects an atmospheric pressure inside the chamber, and the inert gas supplying mechanism may include a second supply amount adjusting part which adjusts the supply amount of the inert gas on the basis of the detection result of the second detection part.

In this embodiment, the adjusting part includes the second detection part which detects the atmospheric pressure inside the chamber, and the inert gas supplying mechanism includes the second supply amount adjusting part which adjusts the supply amount of the inert gas on the basis of the detection result of the second detection part. As a result, it is possible to stably adjust the oxygen concentration and the humidity at a low level.

In the coating apparatus, the adjusting part may include a discharge mechanism which discharges the gas inside the chamber.

In this embodiment, by virtue of the adjusting part including the discharge mechanism which discharges the gas inside the chamber, it is possible to reduce the oxygen concentration and the humidity inside the chamber and to maintain the inside of the chamber at a desired pressure.

In the coating apparatus, the discharge mechanism may include a circulation mechanism which returns at least a part of the discharged inert gas to the inside of the chamber.

In this embodiment, by virtue of the discharge mechanism may include a circulation mechanism which returns at least a part of the discharged inert gas to the inside of the chamber, it is possible to maintain the atmosphere inside the chamber in a stable state.

In the coating apparatus, the circulation mechanism may include a removing member which removes foreign materials from the discharged inert gas.

In this embodiment, by virtue of the circulation mechanism including the removing member which removes the foreign material from the discharged inert gas, it is possible to maintain the atmosphere inside the chamber in a clean state.

In the coating apparatus, the removing member may be an absorbing material which absorbs oxygen, moisture, and the liquid material as the foreign materials.

In this embodiment, by virtue of the removing member being an absorbing material which absorbs oxygen, moisture, and the liquid material as the foreign materials, it is possible to maintain the inside of the chamber in a clean state, and to reduce the oxygen concentration and the humidity inside the chamber.

The coating apparatus may further include a drying part which dries the liquid material coated on the substrate.

In this embodiment, by virtue of the coating apparatus further including a drying part which dries the liquid material coated on the substrate, it is possible to efficiently apply the liquid material on the substrate and dry the liquid material coated on the substrate.

In the coating apparatus, the coating part may include a slit nozzle which ejects the liquid material.

In this embodiment, by virtue of the coating part including the slit nozzle which ejects the liquid material, it is possible to efficiently apply the liquid material on the substrate.

According to another aspect of the present invention, there is provided a coating method including: coating a liquid material including an oxidizable metal on a substrate (coating step); and adjusting at least one of oxygen concentration and humidity inside a chamber having a coating space in which the coating part applies the liquid material on the substrate and a transport space into which the liquid material is transported (adjusting step).

According to the present invention, it is possible to adjust at least one of the oxygen concentration and the humidity inside the chamber having a coating space in which the coating part applies the liquid material on the substrate and a transport space into which the liquid material is transported. As a result, it is possible to prevent the oxidization of the liquid material including the oxidizable metal. Therefore, it is possible to prevent the deterioration in film quality of the coating film.

In the coating method, the adjusting step may include supplying an inert gas to the inside of the chamber (inert gas supplying step).

In this embodiment, by virtue of the adjusting step including the inert gas supplying step of supplying the inert gas to the inside of the chamber, the inside of the chamber can be changed to an inert gas atmosphere, thereby enabling to reduce the oxygen concentration and the humidity inside the chamber.

In the coating method, the adjusting step may include detecting the at least one of oxygen concentration and humidity (detection step), and in the inert gas supplying step, a supply amount of the inert gas may be adjusted on the basis of the detection result in the detection step.

In this embodiment, by virtue of adjusting the supply amount of the inert gas on the basis of the detection result of the at least one of oxygen concentration and humidity, it is possible to stably maintain the oxygen concentration and the humidity inside the chamber to be not more than a predetermined value.

In the coating method, the adjusting step may include detecting an atmospheric pressure inside the chamber (second detection step), and the inert gas supplying step may include a second adjusting step of adjusting the supply amount of the inert gas on the basis of the detection result in the second detection step.

In this embodiment, by virtue of the pressure inside the chamber being detected and the supply amount of the inert gas being adjusted on the basis of the detection result, it is possible to stably control the oxygen concentration and the humidity at a low level.

In the coating method, the adjusting step may include discharging the gas inside the chamber (discharge step).

In this embodiment, by virtue of the gas inside the chamber being discharged in the discharge step, it is possible to reduce the oxygen concentration and the humidity inside the chamber and to maintain the inside of the chamber at a desired pressure.

In the coating method, the discharge step may include a circulation step of returning at least a part of the discharged inert gas to the inside of the chamber.

According to the present invention, virtue of returning at least a part of the discharged inert gas to the inside of the chamber, it is possible to stabilize the atmosphere inside the chamber.

In the coating method, the circulation step may include a removing step of removing a foreign material from the discharged inert gas.

In this embodiment, by virtue of removing the foreign materials from the discharged inert gas, it is possible to maintain the atmosphere inside the chamber in a clean state.

The coating method may further include a drying step of drying the liquid material coated on the substrate.

In this embodiment, by virtue of drying the liquid material coated on the substrate, it is possible to efficiently apply the liquid material on the substrate and dry the liquid material coated on the substrate.

In the coating method, the drying step may be performed in the state where the substrate is disposed at a position deviated from a position where the coating step is performed.

In this embodiment, by virtue of the drying step being performed in the state where the substrate is disposed at a position deviated from a position where the coating step is performed, it is possible to prevent the liquid material used in the coating step from being dried. As a result, it is possible to prevent the liquid material from exhibiting high viscosity and solidifying. Also, it is possible to prevent degeneration of the liquid material including the oxidizable metals.

Thus, according to the present invention, it is possible to suppress the deterioration in film quality of the coating film.

### BRIEF DESCRIPTION OF THE DRAWINGS

FIG. 1 is a diagram showing a configuration of a coating apparatus according to one embodiment of the present invention.

FIG. 2 is a diagram showing a configuration of a part of the coating apparatus according to one embodiment of the present invention.

FIG. 3 is a diagram showing an operation of the coating apparatus according to one embodiment of the present invention.

FIG. 4 is a diagram showing an operation of the coating apparatus according to one embodiment of the present invention.

FIG. 5 is a diagram showing an operation of the coating apparatus according to one embodiment of the present invention.

FIG. 6 is a diagram showing a configuration of a coating apparatus according to another embodiment of the present invention.

### DETAILED DESCRIPTION OF THE INVENTION

Hereinafter, one embodiment of the present invention will be described with reference to the accompanying drawings.

In the respective drawings as below, upon describing the configuration of a coating apparatus, for the purpose of simple marking, an XYZ coordinate system is used to describe the directions in the drawings. In the XYZ coordinate system, the horizontal direction in the drawing is marked as the X direction, and the direction perpendicular to the X direction in a plan view is marked as the Y direction. The direction perpendicular to a plane including the X and Y axes is marked as the Z direction. In the X, Y, and Z directions, the arrow direction in the drawing is the +direction, and the opposite direction of the arrow direction is the −direction.

[Coating Apparatus]

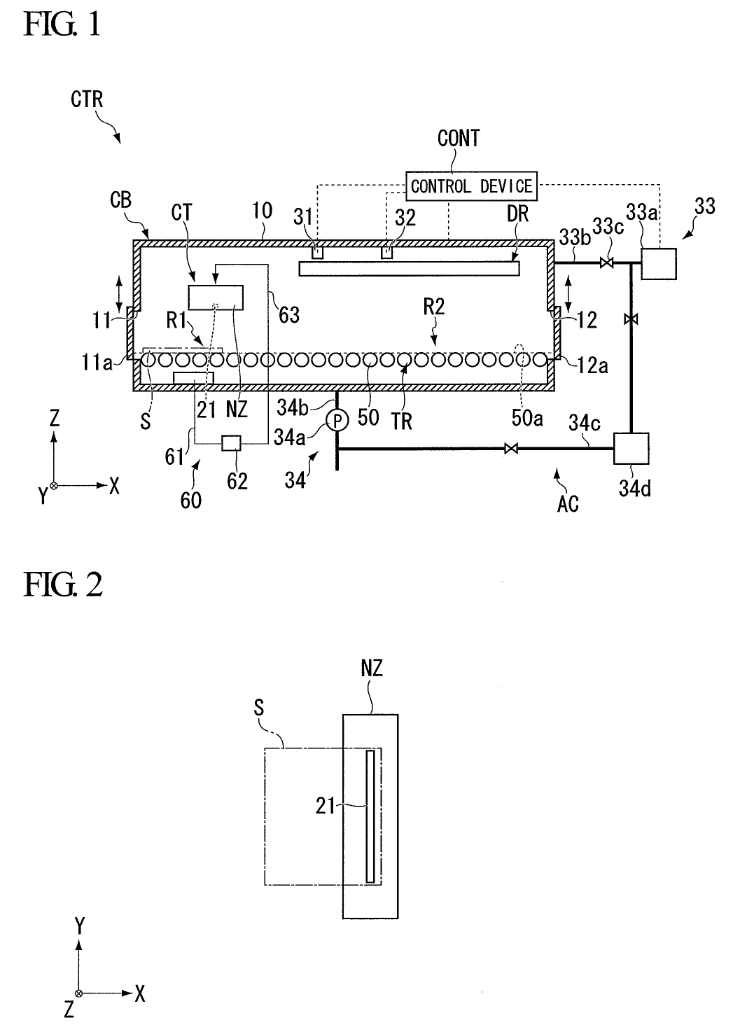

FIG. 1 is a schematic diagram showing a configuration of a coating apparatus CTR according to one embodiment of the present invention.

As shown in FIG. 1, the coating apparatus CTR includes a chamber CB, a coating part CT, a application condition adjusting part AC, a drying part DR, a substrate transporting part TR, and a control device CONT. The coating apparatus CTR is an apparatus which applies a liquid material on a substrate S inside the chamber CB.

In this embodiment, as the liquid material, for example, a liquid composition is used which includes a solvent such as hydrazine and oxidizable metals such as copper (Cu), indium (In), gallium (Ga), and selenium (Se). The liquid composition includes a metal material for forming a light absorbing layer (photoelectric conversion layer) of a CIGS solar cell. Needless to say, as the liquid material, a liquid material in which another oxidizable metal is dispersed in the solution may be used. In this embodiment, as the substrate S, for example, a plate-shaped member made of glass, resin, or the like may be used.

(Chamber)

The chamber CB includes a housing 10, a substrate loading opening 11, and a substrate unloading opening 12. The housing 10 is adapted to accommodate the substrate S. The substrate loading opening 11 and the substrate unloading opening 12 are openings formed in the housing 10. The substrate loading opening 11 is formed in, for example, the −X-direction-side end portion of the housing 10. The substrate unloading opening 12 is formed in, for example, the +X-direction-side end portion of the housing 10. The substrate loading opening 11 and the substrate unloading opening 12 are connected to, for example, a load lock chamber (not shown).

The substrate loading opening 11 is provided with a shutter member 11a. The shutter member 11a is adapted to be movable in the Z direction, and is adapted to open or close the substrate loading opening 11. The substrate unloading opening 12 is provided with a shutter member 12a. In the same manner as the shutter member 11a, the shutter member 12a is adapted to be movable in the Z direction, and is adapted to open or close the substrate unloading opening 12. When the shutter members 11a and 12a are both in a closed state, the inside of the chamber CB is hermetically closed. FIG. 1 shows the state in which the shutter members 11a and 12a are closed.

(Coating Part)

The coating part CT is accommodated in the housing 10 of the chamber CB. The coating part CT includes a slit nozzle NZ which is formed in an elongated shape. The slit nozzle NZ is provided, for example, in the vicinity of the substrate loading opening 11 inside the chamber CB. The slit nozzle NZ is formed to be elongated in, for example, the Y direction.

FIG. 2 is a diagram showing a configuration of the slit nozzle NZ. FIG. 2 shows the configuration when the slit nozzle NZ is viewed from the −Z direction side thereof to the +Z direction side thereof.

As shown in FIG. 2, the slit nozzle NZ has a nozzle opening 21. The nozzle opening 21 is an opening for ejecting a liquid material. The nozzle opening 21 is formed in, for example, the Y direction so as to follow the longitudinal direction of the slit nozzle NZ. The nozzle opening 21 is formed, for example, so that the longitudinal direction thereof is substantially equal to the Y-direction dimension of the substrate S.

The slit nozzle NZ ejects, for example, a liquid material in which four types of metals, namely, Cu, In, Ga, and Se are mixed with a predetermined composition ratio. The slit nozzle NZ is connected to a supply source (not shown) of the liquid material via a connection pipe (not shown). The slit nozzle NZ includes a holding portion which holds the liquid material therein. The slit nozzle NZ includes a temperature controlling mechanism (not shown) which controls the temperature of the liquid material held by the holding portion.

(Application Condition Adjusting Part)

Returning to FIG. 1, the application condition adjusting part AC includes an oxygen concentration sensor 31, a pressure sensor 32, an inert gas supply part 33, and a discharge part 34.

The oxygen concentration sensor 31 detects the oxygen concentration inside the chamber CB, and transmits the detection result to the control device CONT. The pressure sensor 32 detects a pressure inside the chamber CB, and transmits the detection result to the control device CONT. There may be plural numbers of the oxygen concentration sensors 31 and the pressure sensors 32. In FIG. 1, the oxygen concentration sensor 31 and the pressure sensor 32 are mounted to the ceiling portion of the housing 10 of the chamber CB, although they may be provided in other portions.

The inert gas supply part 33 supplies, for example, an inert gas such as nitrogen gas or argon gas to the inside of the housing 10 of the chamber CB. The inert gas supply part 33 includes a gas supply source 33a, a conduit 33b, and a supply amount adjusting part 33c. As the gas supply source 33a, for example, a gas cylinder or the like may be used.

One end of the conduit 33b is connected to the gas supply source 33a, and the other end thereof is connected to the inside of the housing 10 of the chamber CB. The end portion of the conduit 33b connected to the chamber CB is an inert gas supply port in the chamber CB. The inert gas supply port is disposed on the +Z direction side of the housing 10.

The supply amount adjusting part 33c is a part which adjusts the amount of the inert gas supplied to the inside of the housing 10. As the supply amount adjusting part 33c, for example, an electromagnetic valve or a valve which is manually opened or closed may be used. The supply amount adjusting part 33c is provided in, for example, the conduit 33b. The supply amount adjusting part 33c may be directly installed in, for example, the gas supply source 33a, instead of disposing in the conduit 33b.

The discharge part 34 discharges a gas inside the housing 10 of the chamber CB to the outside of the housing 10. The discharge part 34 includes a discharge driving source 34a, a conduit 34b, a conduit 34c, and a removing member 34d. The discharge driving source 34a is connected to the inside of the housing 10 via the conduit 34b. As the discharge driving source 34a, for example, a pump or the like may be used. The conduit 34b has a discharge port which is provided in an end portion thereof provided inside the housing 10. The discharge port is disposed on the −Z direction side of the housing 10.

By such a configuration in which the inert gas supply port is disposed on the +Z direction side of the housing 10 and the discharge port is disposed on the −Z direction side of the housing 10, the gas inside the housing 10 flows in the −Z direction. In this manner, it is possible to suppress the gas inside the housing 10 from whirling around.

One end of the conduit 34c is connected to the discharge driving source 34a, and the other end thereof is connected to the conduit 33b of the inert gas supply part 33. The conduit 34c is used as a circulation path which circulates the gas discharged by the discharge driving source 34a from the inside of the housing 10 to the supply path. In this manner, the discharge part 34 is also used as a circulating mechanism which circulates the gas inside the housing 10. The connection portion of the conduit 34c is not limited to the conduit 33b of the inert gas supply part 33, but for example, the conduit 34c may be directly connected to the inside of the housing 10.

The removing member 34d is provided inside the conduit 34c. As the removing member 34d, for example, an absorbing material for absorbing an oxygen component and moisture contained in the gas circulating in the conduit 34c is used. In this manner, it is possible to clean the circulated gas. The removing member 34d may be disposed at one position inside the conduit 34c, or may be disposed throughout the conduit 34c.

(Drying Part)

The drying part DR is a part which dries the liquid material coated on the substrate S. The drying part DR includes a heating mechanism such as an infrared unit. The drying part DR is adapted to heat and dry the liquid material by using the heating mechanism. The drying part DR is provided at a position not overlapping with the nozzle NZ in plan view. More specifically, the drying part DR is disposed on the +X direction side of the slit nozzle NZ. For this reason, the action of the drying part DR (e.g., irradiation of infrared ray) hardly influences the slit nozzle NZ, and thus the liquid material inside the slit nozzle NZ is hardly dried. By such a configuration in which the drying part DR is not disposed on the +Z direction side of the slit nozzle NZ, it is possible to prevent clogging of the nozzle opening 21 formed in the nozzle NZ, thereby preventing a change in quality of the liquid composition including the oxidizable metal materials.

(Substrate Transporting Part)

The substrate transporting part TR is a part which transports the substrate S inside the housing 10. The substrate transporting part TR includes a plurality of roller members 50. The roller members 50 are arranged in the X direction from the substrate loading opening 11 to the substrate unloading opening 12. Each roller member 50 is adapted to be rotatable about the Y direction serving as the central axis.

The plurality of roller members 50 are formed to have the same diameter, and are disposed at the same position in the Z direction. The +Z-direction-side upper ends of the roller members 50 are adapted to support the substrate S. For this reason, the support positions of the roller members 50 are formed on the same plane, and a transporting plane 50a for the substrate S is formed by the plural roller members 50.

The transporting plane 50a for the substrate S is formed so that a loading position of the substrate S at the substrate loading opening 11 and an unloading position of the substrate S at the substrate unloading opening 12 are equal to each other in the Z direction. In this manner, the substrate S is reliably transported from the substrate loading opening 11 to the substrate unloading opening 12 without any change in the Z-direction position thereof.

In the space above the substrate transporting plane 50a inside the chamber CB, a space on the −Z direction side of the slit nozzle NZ becomes a coating space R1 where the liquid material is applied on the substrate S. In the space above the substrate transporting plane 50a inside the chamber CB, a space on the +X direction side of the slit nozzle NZ becomes a transport space R2 (transporting space R2) where the substrate S coated with the liquid material is transported.

(Control Device)

The control device CONT is a part which has the overall control of the coating apparatus CTR. More specifically, the control device CONT controls an opening-closing operation using the shutter members 11a and 12a of the chamber CB, a transporting operation using the substrate transporting part TR, a coating operation using the coating part CT, a drying operation using the drying part DR, and an adjusting operation using the application condition adjusting part AC. As an example of the adjusting operation, the control device CONT controls an opening degree of the supply amount adjusting part 33c of the inert gas supply part 33 on the basis of the detection result obtained by the oxygen concentration sensor 31 and the pressure sensor 32.

[Coating Method]

Next, a coating method according to one embodiment of the present invention will be described. In this embodiment, a coating film is formed on the substrate S by using the coating apparatus CTR having the above-described configuration. The operations performed by the respective portions of the coating apparatus CTR are controlled by the control device CONT.

The control device CONT adjusts the atmosphere inside the chamber CB to be an inert gas atmosphere. More specifically, an inert gas is supplied to the inside of the chamber CB by using the inert gas supply part 33. In this case, the control device CONT may control the pressure inside the chamber CB by appropriately operating the discharge part 34.

In addition, the control device CONT controls the holding portion of the slit nozzle NZ to hold the liquid material therein. The control device CONT controls the temperature of the liquid material held by the holding portion by using the temperature controlling mechanism inside the slit nozzle NZ. In this manner, the control device CONT controls the slits nozzle NZ so as to be in a state capable of ejecting the liquid material to the substrate S.

When the coating apparatus CTR is in the state capable of ejecting the liquid material to the substrate S, the control device CONT loads the substrate S from the load lock chamber into the chamber CB. More specifically, the control device CONT moves up the shutter member 11a of the substrate loading opening 11, and loads the substrate S into the chamber CB via the substrate loading opening 11.

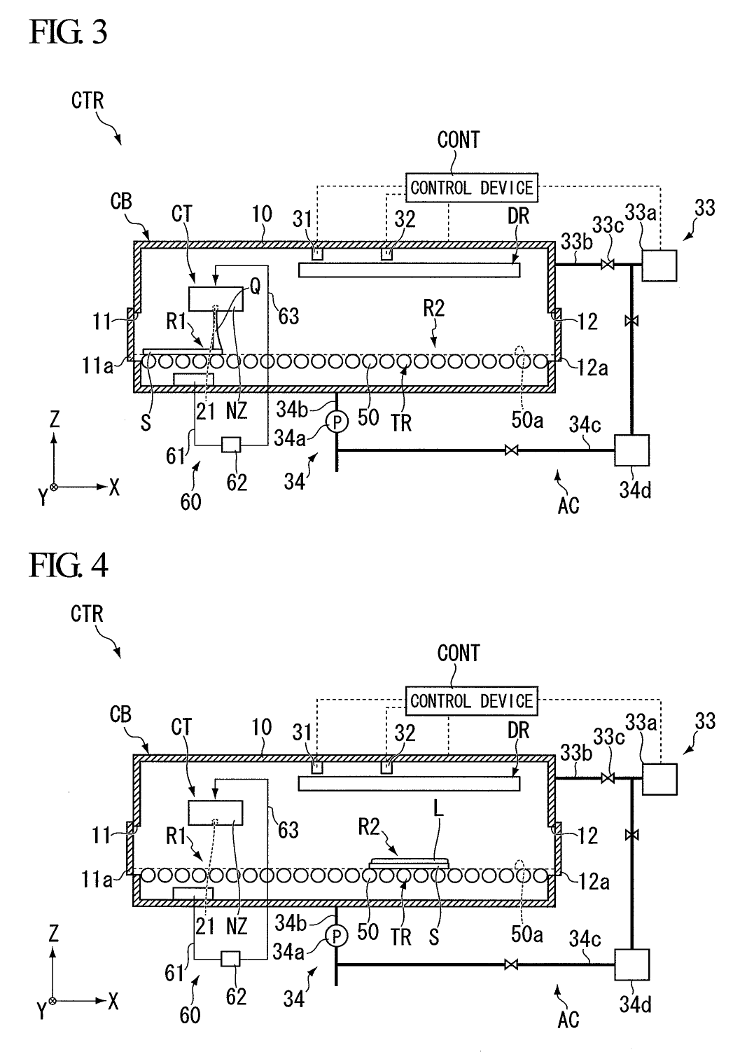

After the substrate S is loaded into the chamber CB, the control device CONT rotates the roller members 50 of the substrate transporting part TR so as to move the substrate S in the +X direction. When the +X-direction-side edge of the substrate S arrives at a position overlapping with the nozzle opening 21 of the slit nozzle NZ as viewed from the Z direction, as shown in FIG. 3, the control device CONT operates the slit nozzle NZ so as to eject a liquid material Q from the nozzle opening 21.

The control device CONT rotates the roller members 50 while ejecting the liquid material Q from the nozzle opening 21 in the state where the position of the slit nozzle NZ is fixed. By this operation, the liquid material is coated on the substrate S from the +X direction side thereof to the −X direction side thereof in accordance with the movement of the substrate S. As shown in FIG. 4, a coating film L of the liquid material is formed on a predetermined area of the substrate S (coating step). After the coating film L is formed on the substrate S, the control device CONT stops the operation of ejecting the liquid material from the nozzle opening 21.

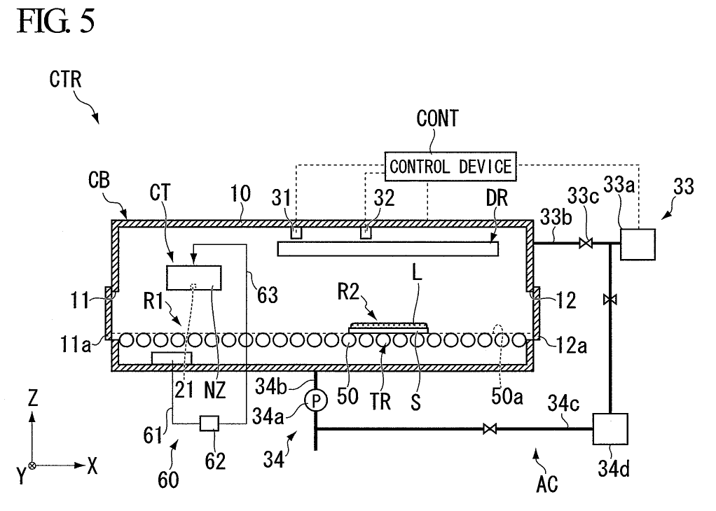

After the ejecting operation stops, as shown in FIG. 5, the control device CONT operates the drying part DR so as to dry the coating film on the substrate S (drying step). The control device CONT, for example, stops the rotation operation of the roller members 50, and operates the drying part DR while the substrate S is in a stationary state. For example, the time required for drying the coating film L on the substrate S and/or the drying temperature is memorized in advance, and the control device CONT performs a drying operation of the coating film L by controlling the drying time and the drying temperature on the basis of the memorized values.

In the case where a part of a light absorbing layer is formed by coating the liquid material Q including oxidizable metals on the substrate S, for example, since Cu, In and the like are metals which are susceptible to oxidation (oxidizable metals), when the oxygen concentration inside the chamber CB is high, the oxidizable metals are oxidized. When the metals are oxidized, the film quality of the coating film formed on the substrate S may deteriorate.

In the present embodiment, the control device CONT adjusts the oxygen concentration inside the chamber CB by using the application condition adjusting part AC (adjusting step). More specifically, the control device CONT supplies an inert gas to the inside of the chamber CB by using the inert gas supply part 33 (inert gas supplying step).

In the inert gas supplying step, the control device CONT first detects the oxygen concentration inside the chamber CB by using the oxygen concentration sensor 31 (detecting step). The control device CONT adjusts the inert gas supply amount by using the supply amount adjusting part 33c on the basis of the detection result obtained in the detecting step, and supplies the inert gas to the inside of the chamber CB. For example, when the detected oxygen concentration exceeds a predetermined threshold value, it is possible to supply the inert gas into the chamber CB. The threshold value may be obtained in advance by a test or simulation, and may be stored in the control device CONT. In addition, for example, a predetermined amount of the inert gas may be constantly supplied into the chamber CB during the coating operation and the drying operation, and the inert gas supply amount can be increased or decreased on the basis of the detection result of the oxygen concentration sensor 31.

In the inert gas supplying step, the control device CONT uses the oxygen concentration sensor 31, and also detects the atmospheric pressure inside the chamber CB by using the pressure sensor 32 (second detecting step). The control device CONT adjusts the inert gas supply amount by using the supply amount adjusting part 33c on the basis of the detection result obtained in the second detection step, and supplies the inert gas into the chamber CB. For example, when the atmospheric pressure inside the chamber CB exceeds a predetermined threshold value, the gas inside the chamber CB is discharged by using the discharge part 34. This threshold value may be obtained in advance by a test or simulation, and may be stored in the control device CONT. In addition, for example, a predetermined amount of the gas inside the chamber CB may be constantly discharged during the coating operation and the drying operation, and the discharge amount can be increased or decreased on the basis of the detection result of the pressure sensor 32.

The gas discharged from the discharge part 34 is circulated to the conduit 33b of the inert gas supply part 33 via the conduits 34b and 34c. When the gas flows through the conduit 34c, the gas passes through the removing member 34d. When the gas passes through the removing member 34d, the oxygen component in the gas is adsorbed by the removing member 34d so as to be removed from the gas (removing step). In this manner, an inert gas having a low oxygen concentration is circulated to the conduit 33b. By circulating the gas inside the chamber CB, it becomes possible to supply the inert gas under stable temperature conditions.

As described above, according to the present embodiment, since the oxygen concentration inside the chamber CB can be suppressed by using the application condition adjusting part AC which controls the oxygen concentration inside the chamber CB, it is possible to prevent the oxidization of the liquid material Q or the oxidizable metals included in the liquid material Q. As a result, it is possible to prevent the deterioration in film quality of the coating film.

The technical scope of the present invention is not limited to the above-described embodiment, but may be appropriately modified into various forms without departing from the spirit of the present invention.

For example, in the above-described embodiment, the oxygen concentration inside the chamber CB is detected so that the inert gas supply amount is controlled on the basis of the detection result, but the present invention is not limited thereto. For example, the humidity inside the chamber CB may be detected so as to control the inert gas supply amount on the basis of the detected humidity. In this case, for example, the chamber CB is provided with a humidity sensor in addition to the oxygen concentration sensor 31. Alternatively, a humidity sensor may be disposed instead of the oxygen concentration sensor 31. In this case, it is desirable that an absorbing material for absorbing the moisture in the gas be provided as the removing member 34d.

In the above-described embodiment, the coating part CT includes the slit nozzle NZ, but the present invention is not limited thereto. For example, a dispenser coating part or an ink jet coating part may be used. Alternatively, for example, the liquid material disposed on the substrate S may be diffused by using a squeezer or the like so as to be coated thereon.

In the above-described embodiment, the slit nozzle NZ constituting the coating part CT is fixed, but the present invention is not limited thereto. For example, a moving mechanism for moving the slit nozzle NZ may be provided so as to move the slit nozzle NZ.

In the above-described embodiment, the roller members 50 are used as the substrate transporting part TR, but the present invention is not limited thereto. For example, the substrate S may be transported by using a floating mechanism to lift the substrate S. In this case, the floating mechanism may be selectively disposed in an area where the slit nozzle NZ is disposed inside the chamber CB. By such a configuration, it is possible to precisely control the film thickness of the coating film formed on the substrate S.

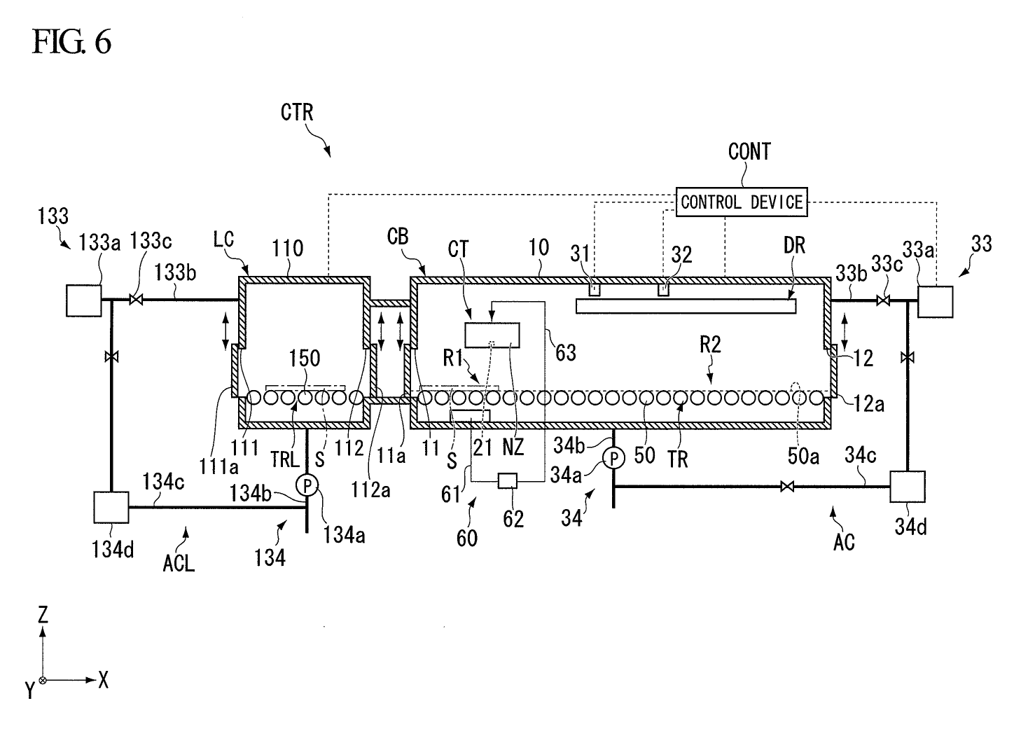

Furthermore, as shown in FIG. 6, in addition to the above-described embodiments, a load lock chamber may be disposed on the upstream side of the substrate loading opening 11. As shown in FIG. 6, the load lock chamber LC has a housing 110, a substrate loading opening 111 and a substrate unloading opening 112. The housing 110 is adapted to accommodate the substrate S. The substrate loading opening 111 and the substrate unloading opening 112 are openings formed in the housing 110. The substrate loading opening 111 is formed in, for example, the −X-direction-side end portion of the housing 110. The substrate unloading opening 112 is formed in, for example, the +X-direction-side end portion of the housing 110. The substrate loading opening 111 is provided with a shutter member 111a. The substrate unloading opening 112 is provided with a shutter member 112a.

Further, the load lock chamber LC has a condition adjusting part ACL and a transporting part TRL. The condition adjusting part ACL includes an oxygen concentration sensor 131, a pressure sensor 132, an inert gas supply part 133, and a discharge part 134. The inert gas supply part 133 includes a gas supply source 133a, a conduit 133b, and a supply amount adjusting part 133c. The discharge part 134 includes a discharge driving source 134a, a conduit 134b, a conduit 134c, and a removing member 134d. The configuration of each part of the condition adjusting part ACL is the same as that of the respective parts of the application condition adjusting part AC in the above-described embodiments. In this manner, the conditions inside the load lock chamber can be adjusted to be the same as the conditions inside the chamber CB. Needless to say, the configuration of the condition adjusting part ACL shown in FIG. 6 is just one example, and may be different from that shown in FIG. 6 (i.e., the configuration may be different from that of the application condition adjusting part AC).

The substrate transporting part TRL is a part which transports the substrate S inside the housing 110. The substrate transporting part TRL includes a plurality of roller members 150. The roller members 150 are arranged in the X direction from the substrate loading opening 111 to the substrate unloading opening 112. Each roller member 150 is adapted to be rotatable about the Y direction serving as the central axis. In this manner, the substrate S can be transported inside the load lock chamber LC.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

What is claimed is:

1. A coating apparatus comprising:
a coating part which applies a liquid material including an oxidizable metal on a substrate;
a chamber having a coating space in which the coating part applies the liquid material on the substrate and a transport space into which the liquid material is transported; and
an adjusting part which adjusts at least one of oxygen concentration and humidity inside the chamber.

2. The coating apparatus according to claim 1,
wherein the liquid material includes hydrazine.

3. The coating apparatus according to claim 1,
wherein the adjusting part includes an inert gas supplying mechanism which supplies an inert gas to the inside of the chamber.

4. The coating apparatus according to claim 3,
wherein the adjusting part includes a detection part which detects the at least one of oxygen concentration and humidity, and
wherein the inert gas supplying mechanism includes a supply amount adjusting part which adjusts a supply amount of the inert gas on the basis of the detection result of the detection part.

5. The coating apparatus according to claim 4,
wherein the adjusting part includes a second detection part which detects an atmospheric pressure inside the chamber, and
wherein the inert gas supplying mechanism includes a second supply amount adjusting part which adjusts the supply amount of the inert gas on the basis of the detection result of the second detection part.

6. The coating apparatus according to claim 3,
wherein the adjusting part includes a discharge mechanism which discharges the gas inside the chamber.

7. The coating apparatus according to claim 6,
wherein the discharge mechanism includes a circulation mechanism which returns at least a part of the discharged inert gas to the inside of the chamber.

8. The coating apparatus according to claim 7,
wherein the circulation mechanism includes a removing member which removes foreign materials from the discharged inert gas.

9. The coating apparatus according to claim 8,
wherein the removing member is an absorbing material which absorbs oxygen, moisture, and the liquid material as the foreign materials.

10. The coating apparatus according to claim 1, further comprising:
a drying part which dries the liquid material coated on the substrate.

11. The coating apparatus according to claim 1,
wherein the coating part includes a slit nozzle which ejects the liquid material.

12. A coating method comprising:
coating a liquid material including an oxidizable metal on a substrate; and
adjusting at least one of oxygen concentration and humidity inside a chamber having a coating space in which the coating part applies the liquid material on the substrate and a transport space into which the liquid material is transported.

13. The coating method according to claim 12,
wherein adjusting the at least one of oxygen concentration and humidity comprises supplying an inert gas to the inside of the chamber.

14. The coating method according to claim 13,
wherein adjusting the at least one of oxygen concentration and humidity further comprises detecting the at least one of oxygen concentration and humidity, and
wherein a supply amount of the inert gas is adjusted on the basis of the detection result of detecting the at least one of oxygen concentration and humidity.

15. The coating method according to claim 14,
wherein adjusting the at least one of oxygen concentration and humidity further comprises detecting an atmospheric pressure inside the chamber, and
wherein a supply amount of the inert gas is adjusted on the basis of the detection result of detecting the atmospheric pressure.

16. The coating method according to claim 13,
wherein adjusting the at least one of oxygen concentration and humidity further comprises discharging the gas inside the chamber.

17. The coating method according to claim 16,
wherein at least a part of the discharged inert gas is returned to the inside of the chamber.

18. The coating method according to claim 17,
wherein foreign materials are removed from the discharged inert gas.

19. The coating method according to claim 12, further comprising:
drying the liquid material coated on the substrate.

20. The coating method according to claim 19,
wherein drying the liquid material is performed in the state where the substrate is disposed at a position deviated from a position where applying the liquid material is performed.
